(19) United States
(12) Patent Application Publication
(10) Pub. No.: US 2014/0186587 A1
(43) Pub. Date: Jul. 3, 2014

(54) TRANSPARENT CONDUCTOR AND APPARATUS INCLUDING THE SAME

(71) Applicant: CHEIL INDUSTRIES INC., Gumi-si (KR)

(72) Inventors: Dong Myeong Shin, Uiwang-si (KR); Kyoung Ku Kang, Uiwang-si (KR); Do Young Kim, Uiwang-si (KR); Young Kwon Koo, Uiwang-si (KR); Oh Hyeon Hwang, Uiwang-si (KR)

(73) Assignee: CHEIL INDUSTRIES INC., Gumi-si (KR)

(21) Appl. No.: 14/141,381

(22) Filed: Dec. 26, 2013

(30) Foreign Application Priority Data
Dec. 27, 2012 (KR) 10-2012-0155600
Oct. 14, 2013 (KR) 10-2013-0122278

(51) Int. Cl. H05K 1/09; H05K 1/02

(52) U.S. Cl. CPC H05K 1/09; H05K 1/028; H05K 1/0274
USPC 428/172; 428/412; 428/336

(57) ABSTRACT

A transparent conductor including: a base layer, a first coating layer on the base layer and having conductivity, and a second coating layer on the first coating layer is disclosed. The base layer, the first coating layer and the second coating layer have refractive indexes of R1, R2 and R3, respectively, at a wavelength of 380 nm to 780 nm, and the transparent conductor has a difference between R1 and R2 (R1−R2) of about 0.05 to about 0.20, and a difference between R2 and R3 (R2−R3) of about 0.01 to about 0.20. An apparatus including the transparent conductor is also disclosed.

### CROSS-REFERENCE TO RELATED APPLICATIONS

This application claims priority to and the benefit of Korean Patent Application No. 10-2012-0155600 filed in the Korean Intellectual Property Office on Dec. 27, 2012, and Korean Patent Application No. 10-2013-0122278 filed in the Korean Intellectual Property Office on Oct. 14, 2013, the entire content of each of which is incorporated herein by reference.

### BACKGROUND

1. Technical Field

The present invention relates to a transparent conductor and an apparatus including the same.

2. Description of the Related Art

Transparent conductors are used as electrode films in touch screen panels, which are included in display apparatuses, flexible displays and the like. Accordingly, transparent conductors have been actively studied in recent years. Transparent conductors should have good properties such as transparency, surface resistance and the like, and also should be flexible for extension to application ranges, such as those of flexible displays. A film, in which indium tin oxide (ITO) films are stacked on two (or both) surfaces of a base film including a polyethylene terephthalate (PET) film, can be used as a transparent conductor. Because the ITO films are deposited on the base film by dry deposition, the ITO films are economical and exhibit good transparency. However, due to certain properties of ITO, ITO films have inherently high resistance and poor flexibility.

Recently, a transparent conductor, in which a conductive layer including metal nanowires such as silver nanowires and the like has been formed and developed. Such a transparent conductor has an advantage of good flexibility. However, because a transparent conductor having a conductive layer including only metal nanowires has high haze, such a transparent conductor has poor optical properties.

### SUMMARY

In accordance with one aspect according to an embodiment of the present invention, a transparent conductor may include: a base layer; a first coating layer on the base layer and having conductivity; and a second coating layer on the first coating layer, wherein the base layer, the first coating layer and the second coating layer have refractive indexes of R1, R2 and R3, respectively, at a wavelength of 380 nm to 780 nm, and the transparent conductor has a difference (i.e., R1−R2) between R1 and R2 of about 0.05 to about 0.20, and a difference (i.e., R2−R3) between R2 and R3 of about 0.01 to about 0.2.

In accordance with another aspect according to another embodiment of the present invention, a transparent conductor may include: a base layer; a first coating layer on the base layer and having conductivity; and a second coating layer on the first coating layer, wherein the transparent conductor has a haze of about 0.01% to about 1.0% and a surface resistance of about 50Ω/□ to about 150Ω/□.

In accordance with a further aspect according to another embodiment of the present invention, an apparatus may include the transparent conductor.

### BRIEF DESCRIPTION OF THE DRAWINGS

The above and other aspects, features and advantages of embodiments of the invention will become more apparent by reference to the following detailed description when considered together with the accompanying drawings, in which:

FIG. 1 is a cross-sectional view of a transparent conductor according to one embodiment of the present invention;

FIG. 2 is a cross-sectional view of a transparent conductor according to another embodiment of the present invention;

FIG. 3 is a cross-sectional view of a transparent conductor according to a further embodiment of the present invention;

FIG. 4 is a cross-sectional view of an optical display apparatus according to one embodiment of the present invention;

FIG. 5 is a cross-sectional view of an optical display apparatus according to another embodiment of the present invention; and

FIG. 6 is a cross-sectional view of an optical display apparatus according to a further embodiment of the present invention.

### DETAILED DESCRIPTION

Certain embodiments of the present invention will be described with reference to the accompanying drawings. It should be understood that the present invention may be modified in different ways and is not limited to the following embodiments. In the drawings, elements irrelevant to the description of embodiments of the invention will be omitted for clarity. Like components will be denoted by like reference numerals throughout the specification. As used herein, terms such as “upper side” and “lower side” are defined with reference to the accompanying drawings. Thus, it will be understood that the term “upper side” can be used interchangeably with the term “lower side”. As used herein, the term “(meth)acrylate” may refer to acrylates and/or methacrylates. Also, in the context of the present application, when a first element is referred to as being “on” a second element, it can be directly on the second element or be indirectly on the second element with one or more intervening elements interposed therebetween.

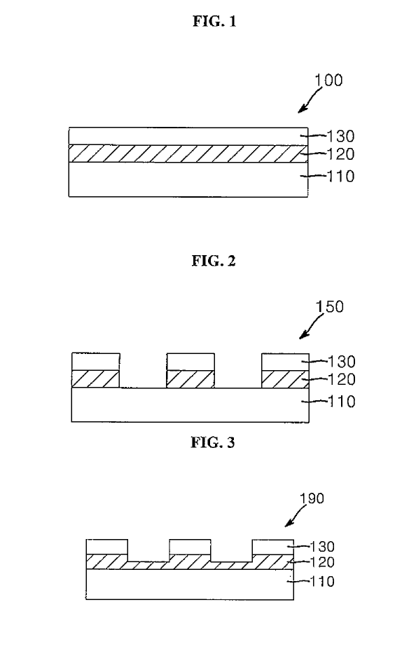

FIG. 1 is a cross-sectional view of a transparent conductor according to one embodiment of the present invention.

Referring to FIG. 1, according to one embodiment of the invention, a transparent conductor 100 may include: a base layer 110; a first coating layer 120, which is on (e.g., formed on) the base layer 110 and is conductive (e.g., exhibits conductivity); and a second coating layer 130 on (e.g., formed on) the first coating layer 120. According to this embodiment, the base layer, the first coating layer and the second coating layer have refractive indexes of R1, R2 and R3, respectively, at a wavelength of 380 nm to 780 nm, and the transparent conductor may have a difference (i.e., R1−R2) between R1 and R2 of about 0.05 to about 0.20, and a difference (i.e., R2−R3) between R2 and R3 of about 0.01 to about 0.2. If the transparent conductor has R1−R2 of less than 0.05 or greater than 0.20, and R2−R3 of less than 0.01 or greater than 0.2, the transparent conductor has high haze and low transmittance (e.g., low light transmittance) and thus can exhibit poor optical properties. For example, the transparent conductor may have R1−R2 of about 0.15 to about 0.20, for example, about 0.15, 0.16, 0.17, 0.18, 0.19, or 0.20, and R2−R3 of about 0.01 to about 0.1, for example, about 0.01, 0.02, 0.03, 0.04, 0.05, 0.06, 0.07, 0.08, 0.09, or 0.1. R1, R2 and R3 may each be measured at a wavelength of 380 nm to 780 nm.

In FIG. 1, although the first coating layer 120 and the second coating layer 130 are respectively on (e.g., formed on) one surface of the base layer 110, the first coating layer 120 and the second coating layer 130 may also be formed on two (e.g., both) surfaces of the base layer 110 without departing from the spirit and scope of the invention.

The transparent conductor may exhibit transparency in the range of visible light, for example, at a wavelength of 400 nm to 700 nm. In one embodiment, the transparent conductor may have a haze of about 1.0% or less, for example, about 0.01% to about 1.0%, and a total light transmittance of about 90% or more, for example, about 90% to about 95%, as measured using a haze meter at a wavelength of 400 nm to 700 nm. Within any of the foregoing ranges, the transparent conductor can be used as a transparent conductor.

The transparent conductor may have a surface resistance (e.g., sheet resistance) of about 150Ω/□ or less, for example, about 50Ω to about 150Ω/□, or about 50Ω/□ to about 100Ω/□, as measured using a 4-point probe tester. Within any of the foregoing ranges, due to low surface resistance, the transparent conductor can be used as an electrode film for touch panels, and can be applied to large area touch panels.

A stacked body including the first coating layer and the second coating layer may be a transparent conductive film or a transparent electrode film, and may be used as a transparent electrode film of touch panels, E-paper or solar cells. The stacked body including the first coating layer and the second coating layer has a thickness of about 0.09 μm to about 0.3 μm, for example, about 0.1 μm to about 0.2 μm, but the stacked body is not limited thereto. Within any of the foregoing ranges, the stacked body including the first coating layer and the second coating layer can be used as a transparent electrode film of touch panels including flexible touch panels.

Because the transparent conductor includes the second coating layer, which is a low refractive index layer having a low refractive index of about 1.30 to about 1.50, for example, about 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, or 1.50 at a wavelength of 380 nm to 780 nm, on (e.g., formed on) the first coating layer having (e.g., exhibiting) conductivity, the transparent conductor can have low haze and high transmittance (e.g., high light transmittance), and thus, the transparent conductor exhibits improved optical properties while providing (e.g., securing) low surface resistance and high flexibility.

Hereinafter, the transparent conductor according to embodiments of the invention will be described in more detail.

The base layer may have a refractive index R1 of about 1.50 to about 1.70, for example, 1.50, 1.51, 1.52, 1.53, 1.54, 1.55, 1.56, 1.57, 1.58, 1.59, 1.60, 1.61, 1.62, 1.63, 1.64, 1.65, 1.66, 1.67, 1.68, 1.69, or 1.70 at a wavelength of 380 nm to 780 nm.

Within any of the foregoing ranges, the base layer has a suitable (e.g., an appropriate) refractive index relative to that of the first coating layer, which can include a metal nanowire, and thus, can improve transparency of the transparent conductor.

The base layer may have a thickness of about 10 μm to about 100 μm. Within this range, the transparent conductor can be used as a transparent electrode film.

The base layer may include retardation films or non-retardation films. In one embodiment, the base layer may include polycarbonate, polyester including polyethylene terephthalate (PET), polyethylene naphthalate and the like, polyolefin, cyclic olefin polymer, polysulfone, polyimide, silicone, polystyrene, polyacryl, and polyvinyl chloride films, but the base layer is not limited thereto.

The base layer may further include functional layers stacked on one surface or two (e.g., both) surfaces thereof. The functional layers may include hard coating layers, anti-corrosive layers, anti-glare coating layers, adhesion promoters, oligomer elusion prevention layers, and the like, but the functional layers are not limited thereto.

The first coating layer may have a refractive index R2 of about 1.35 to about 1.70, about 1.40 to about 1.60, or, for example, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58, 1.59, or 1.60 at a wavelength of 380 nm to 780 nm. Within any of the foregoing ranges, since the first coating layer has a suitable (e.g., an appropriate) refractive index relative to that of the second coating layer, the transparent conductor can have low haze and high transmittance (e.g., high light transmittance), and thus, exhibit improved optical properties.

The first coating layer may have a thickness of about 0.1 μm to about 0.2 μm. Within this range, the transparent conductor can be used as a film for touch panels.

The first coating layer may be conductive (e.g., exhibit conductivity). For example, the first coating layer may be a conductive layer including metal nanowires, and for example, may include a conductive nanowire network formed from metal nanowires. As a result, the first coating layer can impart conductivity to the transparent conductor. For example, the first coating layer may be formed from a composition for a first coating layer including metal nanowires.

The metal nanowires may form a conductive network and thus impart conductivity to the first coating layer and provide good pliablility and flexibility.

The metal nanowires may exhibit better dispersibility than metal nanoparticles due to a shape of the nanowires. In addition, the metal nanowires may significantly decrease surface resistance (e.g., sheet resistance) of the first coating layer, as compared to a layer formed from metal nanoparticles, due to a difference between a shape of the nanoparticles and a shape of the nanowires.

The metal nanowires have an ultrafine line shape having a specific cross-section. For example, the metal nanowires may have a ratio (e.g., L/d, aspect ratio) of length (L) to diameter (d) of the cross-section of about 10 to about 1,000. Within this range, the metal nanowires can realize a highly conductive network even at low density of the nanowires (e.g., at low nanowire concentration), and allow the transparent conductor to have low surface resistance. For example, the metal nanowires may have an aspect ratio of about 500 to about 1,000, or about 500 to about 700.

The metal nanowires may have the diameter (d) of the cross-section of greater than about 0 nm and 100 nm or less. Within this range, the metal nanowires can secure high L/d, and thus, provide (e.g., realize) a transparent conductor having high conductivity (e.g., high electrical conductivity) and low surface resistance. For example, the metal nanowires may have the diameter (d) of the cross-section of about 30 nm to about 100 nm, or about 60 nm to about 100 nm.

The metal nanowires may have a length (L) of about 20 μm or more. Within this range, the metal nanowire can secure high L/d (e.g., high aspect ratio), and thus, provide (e.g., realize) a conductive film having high conductivity (e.g., high electrical conductivity) and low surface resistance. For example, the metal nanowire may have a length (L) of about 20 μm to about 50 μm.

The metal nanowires may include nanowires prepared from any suitable metal. For example, the metal nanowires may include silver nanowires, copper nanowires, gold nanowires, and mixtures thereof, but the metal nanowires are not limited thereto. For example, in some embodiments, the metal nanowires include silver nanowires or a mixture including the silver nanowires, but the metal nanowires are not limited thereto.

The metal nanowires may be prepared by any suitable method typically used in the art, or the metal nanowires may be a commercially available product. For example, the metal nanowires may be prepared through reduction of a metal salt (for example, silver nitrate, AgNO₃) in the presence of a polyol and poly(vinyl pyrrolidone). In some embodiments, the metal nanowires may be a commercially available product (for example, ClearOhm Ink., available from Cambrios Co., Ltd.).

The composition for the first coating layer may further include a solvent for ease of formation of a coating layer and ease of coating the first coating layer on the base film. The solvent may include a main solvent and a co-solvent. The main solvent may include water, acetone and the like, or mixtures thereof, and the co-solvent may include alcohols, such as methanol and the like, or mixtures thereof, for miscibility of water and acetone. However, the main solvent and co-solvent are not limited thereto.

As an overcoating layer, the second coating layer can improve adhesion of the first coating layer to the base film. In addition, as a low refractive index coating layer, the second coating layer can allow the transparent conductor to have low haze and high transmittance (e.g., high light transmittance) as compared with existing transparent conductors, and thus, improve optical properties of the transparent conductor while providing (e.g., securing) good electrical properties and flexibility of the transparent conductor. In one embodiment, the second coating layer may have a refractive index R3 of about 1.30 to about 1.50, or for example, 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, or 1.50, at a wavelength of 380 nm to 780 nm. Within any of the foregoing ranges, the second coating layer can decrease haze of the transparent conductor and improve transmittance (e.g., light transmittance) thereof.

The second coating layer has a thickness of about 0.05 μm to about 0.2 μm, for example, from about 0.05 μm to about 0.1 μm. Within any of the foregoing ranges, the transparent conductor can be used as a film for touch panels.

The second coating layer may be formed from a composition including a fluorine-containing monomer or a polymer thereof. For example, the second coating layer may be formed from a composition including (C1) a fluorine-containing monomer or a polymer thereof, (C2) a non-fluorine monomer, and (C3) an initiator.

The fluorine-containing monomer or polymer thereof may lower a refractive index of the second coating layer, and thus, allow the transparent conductor to have low haze and high transmittance, while forming a film of the second coating layer after curing.

The fluorine-containing monomer or polymer thereof may have a refractive index of about 1.30 to about 1.50 at a wavelength of 380 nm to 780 nm. Within any of the foregoing ranges, the second coating layer can have a low refractive index.

The fluorine-containing monomer may have a molecular weight of about 300 g/mol to about 10,000 g/mol, for example, about 500 g/mol to about 1,000 g/mol, or, for example, about 500, 600, 700, 800, 900, or 1,000 g/mol. Within any of the foregoing ranges, a uniform film of the second coating layer having a low refractive index can be formed and the transparent conductor can have low haze.

The fluorine-containing polymer formed from a fluorine-containing monomer may have a weight average molecular weight of about 10,000 g/mol to about 20,000 g/mol. Within this range, a uniform film of the second coating layer having a low refractive index can be formed and the transparent conductor can have low haze.

The fluorine-containing monomer may include a monomer having fluorine and at least two functional groups (for example, (meth)acrylate groups, or fluorine-containing (meth)acrylate groups) in one molecule.

Fluorine may be present in the fluorine-containing polymer in an amount of about 50% by weight (wt %) to about 90 wt %, for example, about 50, 60, 70, 80, or 90 wt %, based on the total weight of the fluorine-containing polymer formed from the fluorine-containing monomer. Within any of the foregoing ranges, the transparent conductor can exhibit decreased haze and improved transmittance (e.g., improved light transmittance).

The fluorine-containing monomer may include, for example, a pentaerythritol backbone, a dipentaerythritol backbone, a trimethylolpropane backbone, a ditrimethyloipropane backbone, a cyclohexyl backbone, a linear backbone, or a mixture thereof, but the fluorine-containing monomer is not limited thereto.

For example, the fluorine-containing monomer may be represented by any of Formulae 1 to 19:

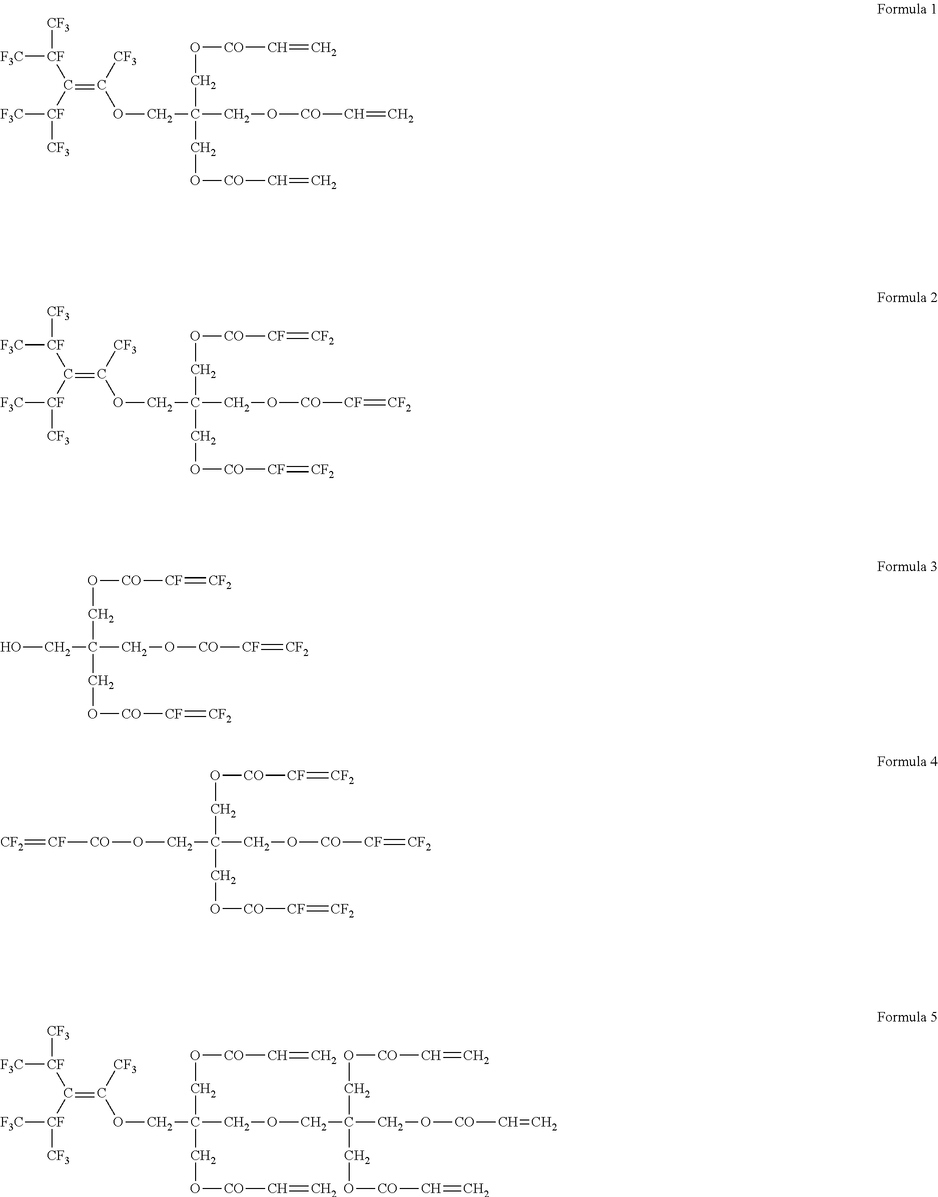

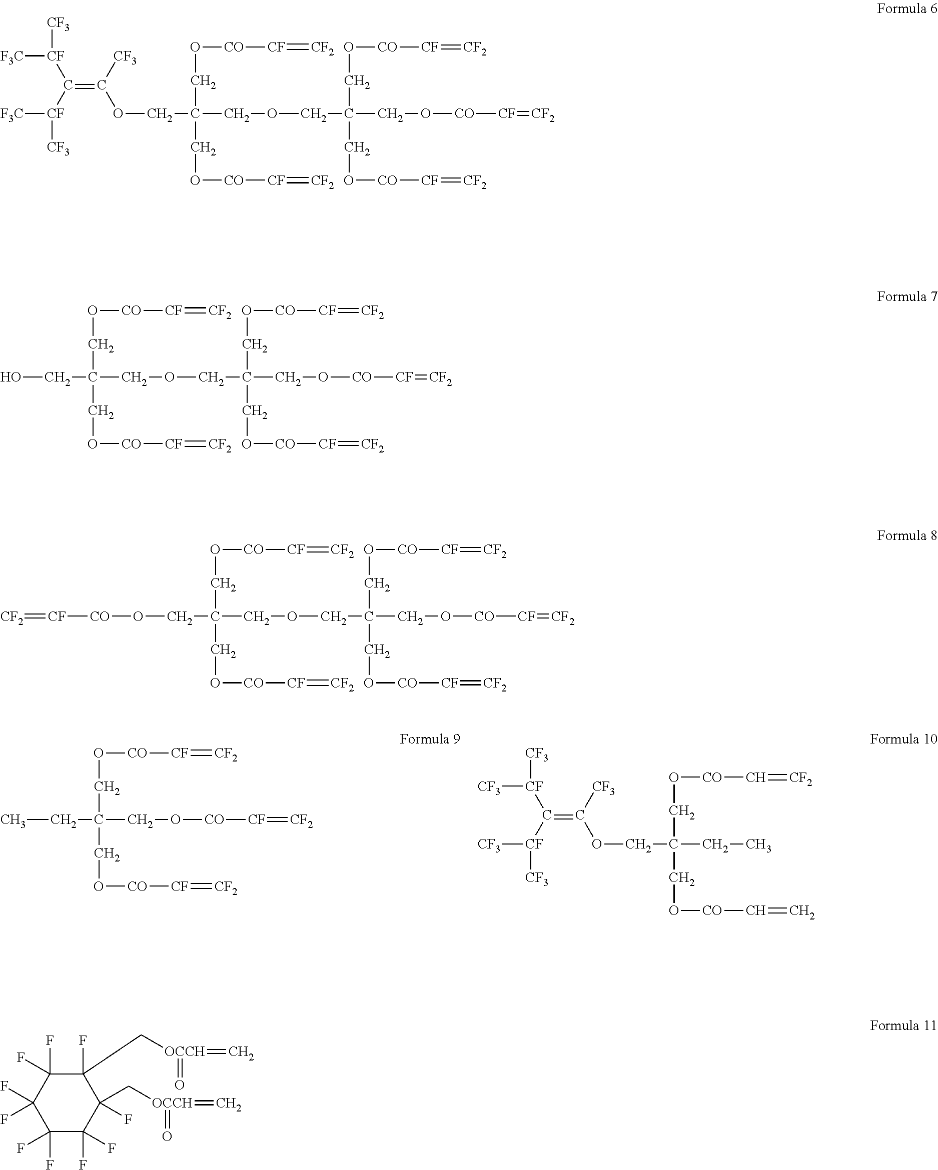

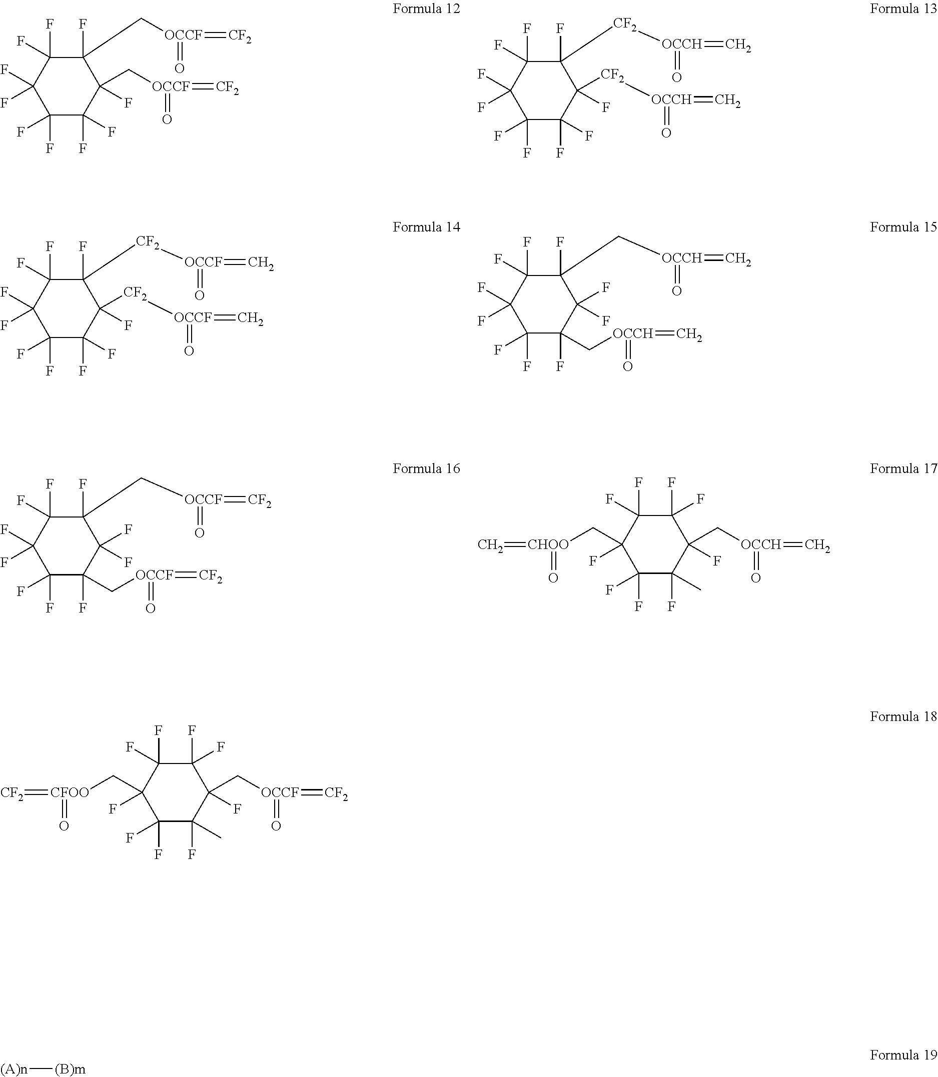

In Formula 19, A is a fluorine-containing C₁ to C₂₀ hydrocarbon group; B is an acrylate group, methacrylate group, fluorine-substituted acrylate group, or fluorine-substituted methacrylate group; n is an integer from 1 to 6; and m is an integer from 1 to 16.

In Formula 19, the “hydrocarbon group” may be an alkyl group or an alkylene group.

The fluorine-containing monomer or polymer thereof may be present in the composition for forming the second coating layer in an amount of about 2 wt % to about 95 wt %, for example, about 5 wt % to about 91 wt %, for example, about 2 wt % to about 50 wt %, or, for example, about 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 wt %, based on the total weight of solids in the composition for forming the second coating layer. Within any of the foregoing ranges, the fluorine-containing monomer or polymer thereof can provide a second coating layer having a low index of refraction, and thus, allow the transparent conductor to have low haze and high transmittance (e.g., high light transmittance).

The fluorine-containing monomer or polymer thereof may be present in the composition for forming the second coating layer in an amount of about 2 parts by weight to about 95 parts by weight, for example, about 5 parts by weight to about 95 parts by weight, based on 100 parts by weight of (C1)+(C2). Within any of the foregoing ranges, the second coating layer can form a uniform film, and thus, allow the transparent conductor to exhibit low haze and improved transmittance (e.g., improved light transmittance).

The non-fluorine monomer is free from fluorine (e.g., completely free from fluorine) and may include a monofunctional or polyfunctional monomer having a curing reaction group, for example, a (meth)acrylate group. The non-fluorine monomer may be polymerization-cross-linked (e.g., cross-linked through polymerization) with the fluorine-containing monomer or polymer thereof through processes of heating and curing the composition, and thus, may form the second coating layer.

The non-fluorine monomer may have a refractive index of about 1.30 to about 1.50, for example, 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, or 1.50 at a wavelength of 380 nm to 780 nm. Within any of the foregoing ranges, the non-fluorine monomer can provide (e.g., realize) a second coating layer having a suitably (e.g., sufficiently) low refractive index.

The non-fluorine monomer may have a molecular weight of about 250 g/mol to about 1,000 g/mol. Within this range, since the non-fluorine monomer has an appropriate number of functional groups, the second coating layer does not suffer from hardness deterioration.

For example, the non-fluorine monomer may include dipentaerythritol hexa(meth)acrylate, trimethylolpropane tri(meth)acrylate, pentaerythritol tetra(meth)acrylate, di(trimethylolpropane)tetra(meth)acrylate, pentaerythritol tri(meth)acrylate, tris(2-hydroxyethyl)isocyanurate tri(meth)acrylate, glycerol tri(meth)acrylate, ethyleneglycol di(meth)acrylate, neopentylglycol di(meth)acrylate, hexanediol di(meth)acrylate, trimethylolpropane di(meth)acrylate, dipentaerythritol penta(meth)acrylate, pentaerythritol tri(meth)acrylate, cyclodecane dimethanol di(meth)acrylate, or a mixture thereof, but the non-fluorine monomer is not limited thereto.

The non-fluorine monomer may be present in the composition for forming the second coating layer in an amount of about 0.1 wt % to about 95 wt %, for example, about 0.2 wt % to about 40 wt % or about 8 wt % to about 92 wt %, based on the total weight of solids in the composition for forming the second coating layer. Within any of the foregoing ranges, the second coating layer can maintain external appearance thereof, and exhibit improved adhesion to the base layer and physical properties.

In one embodiment, the composition for forming the second coating layer may include a mixture of a hexafunctional monomer and a trifunctional monomer as the non-fluorine monomer. The mixture may include about 0.1 wt % to about 99.9 wt %, for example, about 0.1 wt % to about 90 wt % of the hexafunctional monomer, and about 0.1 wt % to about 99.9 wt %, for example, about 0.1 wt % to about 10 wt % of the trifunctional monomer, based on the total weight of the mixture. Within any of the foregoing ranges, the transparent conductor can provide (e.g., secure) adhesion between the base layer and the second coating layer, and can exhibit low haze and high transmittance (e.g., high light transmittance).

The non-fluorine monomer may be present in the composition for forming the second coating layer in an amount of about 5 parts by weight to about 98 parts by weight, for example, about 5 parts by weight to about 95 parts by weight, based on 100 parts by weight of (C1)+(C2). Within any of the foregoing ranges, the second coating layer can exhibit improved adhesion to the base layer and improved physical properties.

The initiator may be any suitable initiator without limitation as long as the initiator can absorb light at an absorption wavelength of about 150 nm to about 500 nm to induce (e.g., exhibit) photoreaction. For example, the initiator may include phosphine oxide initiators, α-hydroxyketone initiators, and the like, but the initiator is not limited thereto. For example, the initiator may include bis-acyl-phosphine oxide (BAPO), diphenyl(2,4,6-trimethylbenzoyl)phosphine oxide (TPO), 1-hydroxycyclohexylphenylketone, and mixtures thereof, but the initiator is not limited thereto.

The initiator may be present in the composition for forming the second coating layer in an amount of about 0.1 wt % to about 10 wt %, for example, about 0.1 wt % to about 5 wt %, based on the total weight of solids in the composition for the second coating layer in terms of solid content. Within any of the foregoing ranges, a monomer can be suitably (e.g., sufficiently) cured without the residual initiator.

The initiator may be present in the composition for forming the second coating layer in an amount of about 0.01 parts by weight to about 5 parts by weight, for example, about 0.1 parts by weight to about 1 part by weight, based on 100 parts by weight of (C1)+(C2). Within any of the foregoing ranges, a cured film of the second coating layer can exhibit adhesion to the base layer and chemical resistance.

The composition for forming the second coating layer may further include hollow silica fine particles. The hollow silica fine particles may improve a strength of the second coating layer. The hollow silica fine particles may be subjected to surface modification (e.g., surface treated) with a fluorine-containing resin. As a result, the second coating layer can have a lower refractive index.

The hollow silica fine particles may be present in the composition for forming the second coating layer in an amount of about 0.1 parts by weight to about 10 parts by weight, based on 100 parts by weight of solids in the composition for forming the second coating layer. The hollow silica fine particles may have an average particle diameter of about 30 nm to about 60 nm. Within this range, the second coating layer can exhibit good transparency.

The transparent conductor may be prepared from the base layer, the composition for forming the first coating layer, and the composition for forming the second coating layer using any suitable method commonly used in the art. For example, the composition for forming the first coating layer is coated onto a surface of the base layer, followed by drying and baking. Next, the composition for forming the second coating layer is coated onto the first coating layer, followed by drying, baking, and UV curing at about 500 mJ/cm² or more, for example, about 500 mJ/cm² to about 1000 mJ/cm², thereby forming the second coating layer. The first and second coating layers are formed on a surface (e.g., at least one surface) of the base layer, and in some embodiments, are formed on only one surface thereof.

FIG. 2 is a cross-sectional view of a transparent conductor according to another embodiment of the invention. Referring to FIG. 2, a transparent conductor 150 may include: a base layer 110; a first coating layer 120 on (e.g., formed on) the base layer 110 and having (e.g., exhibiting conductivity); and a second coating layer 130 on (e.g., formed on) the first coating layer 120. The base layer 110, the first coating layer 120 and the second coating layer 130 have refractive indexes of R1, R2 and R3, respectively, at a wavelength of 380 nm to 780 nm, and the transparent conductor may have a difference (i.e., R1−R2) between R1 and R2 of about 0.05 to about 0.20 and a difference (i.e., R2−R3) between R2 and R3 of about 0.01 to about 0.2, and the first coating layer 120 and the second coating layer 130 may be patterned. In FIG. 2, the transparent conductor 150 is the same (or substantially the same) as the transparent conductor 100 according to the above embodiment of the invention in FIG. 1 except that both the first coating layer 120 and the second coating layer 130 are patterned.

In FIG. 2, the first and second coating layers 120, 130 are shown as being formed on one surface of the base layer 110 is shown, but the first and second coating layers 120, 130 may be formed on two (e.g., both) surfaces of the base layer 110 without departing from the spirit and scope of the invention.

Each of the first and second coating layers 120, 130 may be patterned, for example, by wet etching and the like, but the method of patterning is not limited thereto.

FIG. 3 is a cross-sectional view of a transparent conductor according to a further embodiment of the present invention. Referring to FIG. 3, a transparent conductor 190 may include: a base layer 110; a first coating layer 120 on (e.g., formed on) the base layer 110 and having (e.g., exhibiting) conductivity; and a second coating layer 130 on (e.g., formed on) the first coating layer 120. The base layer 110, the first coating layer 120 and the second coating layer 130 have refractive indexes of R1, R2 and R3, respectively at a wavelength of 380 nm to 780 nm, and the transparent conductor may have a difference (i.e., R1−R2) between R1 and R2 of about 0.05 to about 0.20 and a difference (i.e., R2−R3) between R2 and R3 of about 0.01 to about 0.2, and the first coating layer 120 may be partially patterned and the second coating layer 130 may be completely patterned. In FIG. 3, the transparent conductor 190 is the same (or substantially the same) as the transparent conductor 100 according to the one embodiment of the invention in FIG. 1 except that the first coating layer 120 is partially patterned and the second coating layer 130 is completely patterned.

Each of the first and second coating layers 120, 130 may be patterned, for example, by wet etching and the like, but the method of patterning is not limited thereto.

An apparatus according to an embodiment of the invention may include the transparent conductor according to an embodiment of the invention. Examples of the apparatus include, for example, optical display apparatuses including touch screen panels, flexible displays and the like, E-paper, solar cells, and the like, but the apparatus is not limited thereto.

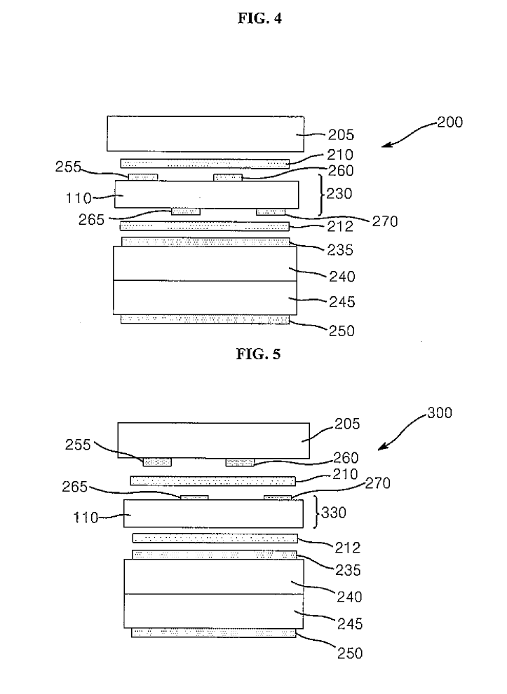

FIGS. 4 to 6 are sectional views of optical display apparatuses according embodiments of the invention.

Referring to FIG. 4, an optical display apparatus 200 may include a transparent electrode body 230 including: a base layer 110, first and second electrodes 255, 260 on (e.g., formed on) an upper surface of the base layer 110, and third and fourth electrodes 265, 270 on (e.g., formed on) a lower surface of the base layer 110. The optical display apparatus 200 further includes: a window glass 205 above the first and second electrodes 255, 260; a first polarizing plate 235 below the third and fourth electrodes 265, 270; a color filter (CF) glass 240 on (e.g., formed on) a lower surface of the first polarizing plate 235; a panel 245 on (e.g., formed on) a lower surface of the CF glass 240 and including a thin film transistor (TFT) glass; and a second polarizing plate 250 on (e.g., formed on) a lower surface of the panel 245. The transparent electrode body 230 is prepared by forming the first, second, third and fourth electrodes through patterning the transparent conductor embodiments of the present invention using a predetermined (or set) process (for example, etching, and the like), respectively. The transparent electrode body 230, for example, the first, second, third and fourth electrode 255,260,265, 270 may include an overcoating layer, such as the second coating layer according to an embodiment of the invention, to exhibit improved optical properties. The first and second electrodes 255, 260 may be Rx electrodes and the third and fourth electrodes 265, 270 may be Tx electrodes, or vice versa. The window glass 205 performs a screen display function in the optical display apparatus and may be prepared from a glass material. The first and second polarizing plates 235, 250 impart polarization capabilities to the optical display apparatus, may polarize external or internal light, and may include a polarizer or a stacked body of a polarizer and a protective film. Here, each of the polarizer and the protective film may include any suitable film commonly used in the art. Adhesive films 210, 212 are placed between the window glass 205 and the transparent electrode body 230, and between the transparent electrode body 230 and the first polarizing plate 235, respectively, thereby maintaining adherence between the transparent electrode body 230, the window glass 205 and the first polarizing plate 235. The adhesive films 210, 212 may be a typical adhesive film, for example, an optically clear adhesive (OCA) film.

Referring to FIG. 5, an optical display apparatus 300 may include a transparent electrode body 330 including: a base layer 110, and third and fourth electrodes 265, 270 on (e.g., formed on) an upper surface of the base layer 110. The optical display apparatus 300 further includes: a window glass 205 above the third and fourth electrodes 265, 270 and including first and second electrodes 255, 260 on (e.g., formed on) a lower surface thereof; a first polarizing plate 235 below the transparent electrode body 330; a color filter (CF) glass 240 on (e.g., formed on) a lower surface of the first polarizing plate 235; a panel 245 on (e.g., formed on) a lower surface of the CF glass 240 and including a thin film transistor (TFT) glass; and a second polarizing plate 250 on (e.g., formed on) a lower surface of the panel 245. The transparent electrode body 330 is prepared by forming the third and fourth electrodes 265, 270 through patterning of the transparent conductor of the present invention using a predetermined (or set) method (for example, etching, and the like). The transparent electrode body 330 may include an overcoating layer, such as the second coating layer according to an embodiment of the invention, to exhibit improved optical properties, and may improve optical efficiency for light transmitted through the second polarizing plate 250, the CF glass 240, the TFT glass 245, and the first polarizing plate 235. The first and second electrodes 255, 260 may be formed using any suitable method commonly used in the art for forming an electrode. Adhesive films 210, 212 are placed between the window glass 205 and the transparent electrode body 330 and between the transparent electrode body 330 and the first polarizing plate 235, respectively, thereby maintaining adhesion between the transparent electrode body 330, the window glass 205 and the first polarizing plate 235.

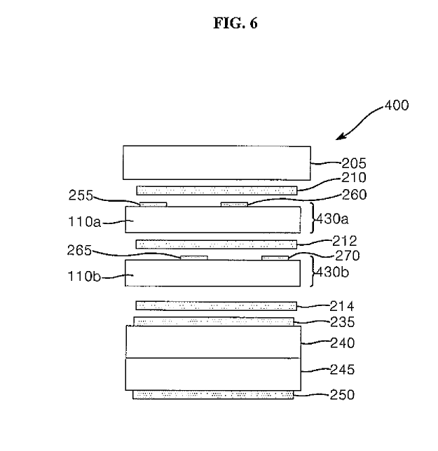

Referring to FIG. 6, an optical display apparatus 400 may include a first transparent electrode body 430a including: a first base layer 110a, and first and second electrodes 255, 260 on (e.g., formed on) an upper surface of the first base layer 110a. The optical display apparatus 400 further includes: a second transparent electrode body 430b below (e.g., formed below) the first transparent electrode body 430a and including a second base layer 110b and third and fourth electrodes 265, 270 on (e.g., formed on) an upper surface of the second base layer 110b; a first polarizing plate 235 below the second transparent electrode body 430b; a color filter (CF) glass 240 on (e.g., formed on) a lower surface of the first polarizing plate 235; a panel 245 on (e.g., formed on) a lower surface of the CF glass 240 and including a thin film transistor (TFT) glass; and a second polarizing plate 250 on (e.g., formed on) a lower surface of the panel 245. The first and second transparent electrode bodies 430a, 430b are prepared by forming the first, second, third and fourth electrodes through patterning the transparent conductor of embodiments of the present invention using a predetermined (or set) method. In addition, the base layer may be a retardation film and have an effect of compensation of viewing angle, and thus compensate viewing angle for light transmitted through the second polarizing plate 250, the CF glass 240, the TFT glass 245, and the first polarizing plate 235. Adhesive films 210, 212, 214 are placed between the first transparent electrode body 430a and the window glass 205, between the first and second transparent electrode bodies 430a, 430b, and between the second transparent electrode body 430b and the first polarizing plate 235, respectively, thereby maintaining adhesion between the transparent electrode bodies, the window glass, and the first polarizing plate. The adhesive films 210, 212, 214 may be any suitable adhesive films commonly used in the art, for example, optically clear adhesive (OCA) films. In addition, the base layers may have a stacked structure, in which resin films are stacked via adhesives or the like.

Hereinafter, embodiments of the present invention will be described with reference to some examples. However, it should be noted that these examples are provided for illustration only and are not to be construed in any way as limiting the present invention.

### Preparative Example

### Preparation of Composition for Forming First Coating Layer

48 parts by weight of silver nanowires (Clearohm Ink., available from Cambrios Co., Ltd., aspect ratio: 500) was introduced into 52 parts by weight of ultrapure distilled water, followed by stirring, thereby preparing a composition for forming a first coating layer.

The components used in Examples and Comparative Examples were as follows.

(A) Fluorine-containing monomer or polymer thereof: (A1) AR-110 (available from DAIKIN Co., Ltd.), (A2) LINC-3A (available from KYOEISHA Co., Ltd., Formula 2)

(B) Non-fluorine monomer: (B1) Trimethylolpropane triacrylate (TMPTA), (B2) Dipentaerythritol hexaacrylate (DPHA)

(C) Initiator: Bis-acyl-phosphine oxide (BAPO, Darocure 819W, available from CIBA Co., Ltd.)

(D) Urethane acrylate

(E) Composition for first coating layer: The composition of Preparative Example

(F) Base layer: Polycarbonate film (thickness: 50 μm, refractive index at a wavelength of 550 nm: 1.63)

### Example 1

0.45 parts by weight of TMPTA and 0.01 parts by weight of the initiator were introduced into 95 parts by weight of propylene glycol monomethyl ether (PGME) as a solvent, and dissolved therein. Next, 4.5 parts by weight of AR-110 (available from DAIKIN Co., Ltd.) was added to the resulting solution and dissolved therein, thereby preparing a composition for forming a second coating layer. The composition for forming a first coating layer was coated onto the base layer using wire bar-coating, followed by drying in an oven at 80° C. for 2 minutes. Next, the composition for forming a second coating layer was coated onto the dried first coating layer using a spin coater, followed by drying in an oven at 80° C. for 2 minutes. The coating layers were subjected to UV curing at 500 mJ/cm² in a nitrogen atmosphere, thereby preparing a transparent conductor.

### Example 2

0.21 parts by weight of TMPTA, 7.5 parts by weight of DPHA and 0.23 parts by weight of the initiator were introduced into 99 parts by weight of propylene glycol monomethyl ether (PGME) as a solvent, and then dissolved therein. Next, 0.5 parts by weight of LINC-3A (available from KYOEISHA Co., Ltd.) was added to the resulting solution and dissolved therein, thereby preparing a composition for forming a second coating layer. The composition for forming a first coating layer was coated onto the base layer by wire bar-coating, followed by drying in an oven at 80° C. for 2 minutes. Next, the composition for forming a second coating layer was coated onto the dried first coating layer using a spin coater, followed by drying in an oven at 80° C. for 2 minutes. The coating layers were subjected to UV curing at 500 mJ/cm² in a nitrogen atmosphere, thereby preparing a transparent conductor.

### Comparative Example 1

2 parts by weight of a urethane acrylate and 0.01 parts by weight of the initiator were introduced into 98 parts by weight of propylene glycol monomethyl ether (PGME) as a solvent, and then dissolved therein, thereby preparing a solution B. The composition for forming a first coating layer was coated onto the base layer by wire bar-coating, followed by drying in an oven at 80° C. for 1 minute and then baking in an oven at 120° C. for 1 minute. The solution B was coated onto the first coating layer by wire bar-coating, followed by drying in an oven at 80° C. for 1 minute and then baking in an oven at 120° C. for 1 minute. Next, the coating layers were subjected to UV curing at 500 mJ/cm² in a nitrogen atmosphere, thereby preparing a transparent conductor, in which a 150 nm-thick conductive film including a cured product of the metal nanowires, the urethane acrylate and the initiator was stacked on one surface of the base film.

### Comparative Example 2

A transparent conductor was prepared as in Example 1 except that 5 parts by weight of TMPTA was used instead of 4.5 parts by weight of AR-110 (DAIKIN Co., Ltd.).

The transparent conductors prepared in Examples and Comparative Examples were evaluated as to the following properties. Results are shown in Table 1.

(1) Difference between refractive indexes: Refractive indexes of the coating layers were measured using an ellipsometer at a wavelength of 380 nm to 780 nm. From the measured results, a difference between refractive indexes was calculated. R1, R2 and R3 were the refractive indexes of the base layer, the first coating layer and second coating layer, respectively.

(2) Haze and Total light transmittance (%): Haze and total light transmittance were measured on the transparent conductors at a wavelength of 400 nm to 700 nm using a haze meter.

(3) Surface resistance (Ω/□): With 4 probes of a contact-type surface resistance tester MCP-T610 (available from Mitsubishi Chemical Analytech Co., Ltd.) contacting a surface of the second coating layer of each of the transparent conductors, surface resistance was measured after 10 seconds.

(4) IPA rubbing: After isopropanol (IPA) was dropped onto the second coating layer using pipettes and then rubbed ten times thereon using a wiper, change in external appearance and resistance of the second coating layer was observed. No change in both external appearance and resistance was evaluated as ‘Good’, and change in at least one of external appearance and resistance was evaluated as ‘Not Good (NG)’.

TABLE 1

| | | | Comparative | Comparative |
|---|---|---|---|---|
| | Example 1 | Example 2 | Example 1 | Example 2 |
| Difference between | 0.19 | 0.19 | 0.19 | 0.19 |
| R1 and R2, | | | | |
| R1-R2 | | | | |
| Difference between | 0.06 | 0.01 | −0.08 | −0.03 |
| R2 and R3, | | | | |
| R2-R3 | | | | |
| Haze (%) | 0.77 | 0.75 | 1.14 | 1.2 |
| Total light | 91.95 | 90.06 | 90.18 | 90.20 |
| transmittance (%) | | | | |
| Surface resistance | 64 to 74 | 58 to 62 | 70 to 80 | 60 to 70 |
| (Ω/□) | | | | |
| IPA rubbing | Good | Good | Good | NG |

As shown in Table 1, the transparent conductors according to an embodiment of the invention, in which the second coating layer including a low refractive fluorine resin was formed, exhibited good optical properties due to low haze and high transmittance thereof, and had low surface resistance. Conversely, the transparent conductor of Comparative Example 1, in which the second coating layer was not formed and an overcoating layer including a urethane acrylate was formed, had high haze and high surface resistance, and thus could not realize effects of embodiments of the present invention. In addition, the transparent conductor of Comparative Example 2, in which the second coating layer free from a fluorine-containing monomer or polymer was formed, had high haze and suffered from problems in terms of chemical resistance and adhesion to the base layer. Further, when the transparent conductor included hollow silica coated with a low refractive resin, the transparent conductor had problems of increased surface resistance and high haze. Thus, according to embodiments of the invention, the transparent conductor has improved optical properties due to low haze and high transmittance thereof, exhibits good properties in terms of adhesion to the base layer, solvent resistance and flexibility, and has low surface resistance.

While certain embodiments of the present invention have been illustrated and described herein, it will be understood that various modifications, changes, alterations, and equivalent embodiments can be made by those skilled in the art without departing from the spirit and scope of the invention as defined by the following claims, and equivalents thereof. Throughout the text and claims, use of the word “about” reflects the penumbra of variation associated with measurement, significant figures, and interchangeability, all as understood by a person having ordinary skill in the art to which this disclosure pertains. Additionally, throughout this disclosure and the accompanying claims, it is understood that even those ranges that may not use the term “about” to describe the high and low values are also implicitly modified by that term, unless otherwise specified.

What is claimed is:

1. A transparent conductor comprising:
a base layer;
a first coating layer on the base layer and having conductivity; and
a second coating layer on the first coating layer,
wherein the base layer, the first coating layer and the second coating layer have refractive indexes of R1, R2 and R3, respectively, at a wavelength of 380 nm to 780 nm, and the transparent conductor has a difference between R1 and R2 (R1−R2) of about 0.05 to about 0.20, and a difference between R2 and R3 (R2−R3) of about 0.01 to about 0.2.

2. A transparent conductor comprising:
a base layer;
a first coating layer on the base layer and having conductivity; and
a second coating layer on the first coating layer,
wherein the transparent conductor has a haze of about 0.01% to about 1.0% and a surface resistance of about 50Ω/□ to about 150Ω/□.

3. The transparent conductor according to claim 1, wherein the first coating layer and second coating layer are patterned.

4. The transparent conductor according to claim 1, wherein the first coating layer comprises a metal nanowire.

5. The transparent conductor according to claim 1, wherein the second coating layer has a refractive index of about 1.30 to about 1.50 at a wavelength of 380 nm to 780 nm.

6. The transparent conductor according to claim 1, wherein the second coating layer has a thickness of about 0.05 μm to about 0.2 μm.

7. The transparent conductor according to claim 1, wherein the second coating layer comprises a fluorine-containing monomer or a polymer thereof.

8. The transparent conductor according to claim 7, wherein the fluorine-containing monomer has a molecular weight of about 500 g/mol to about 1000 g/mol.

9. The transparent conductor according to claim 7, wherein the fluorine-containing monomer has a pentaerythritol backbone, a dipentaerythritol backbone, a trimethylolpropane backbone, a ditrimethylol propane backbone, a cyclohexyl backbone, a linear backbone, or a combination thereof.

10. The transparent conductor according to claim 7, wherein the fluorine-containing monomer comprises any of Formulae 1 to 19: 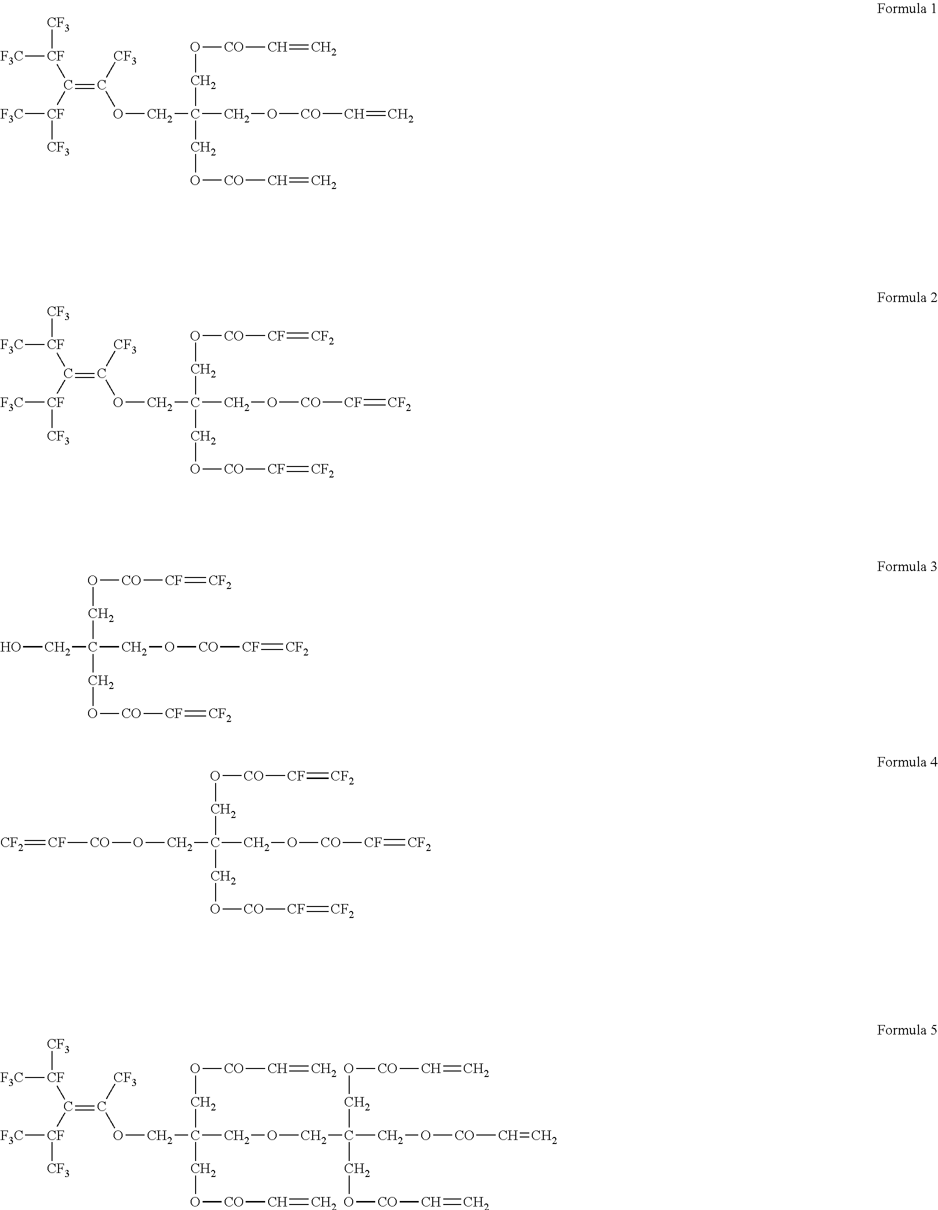 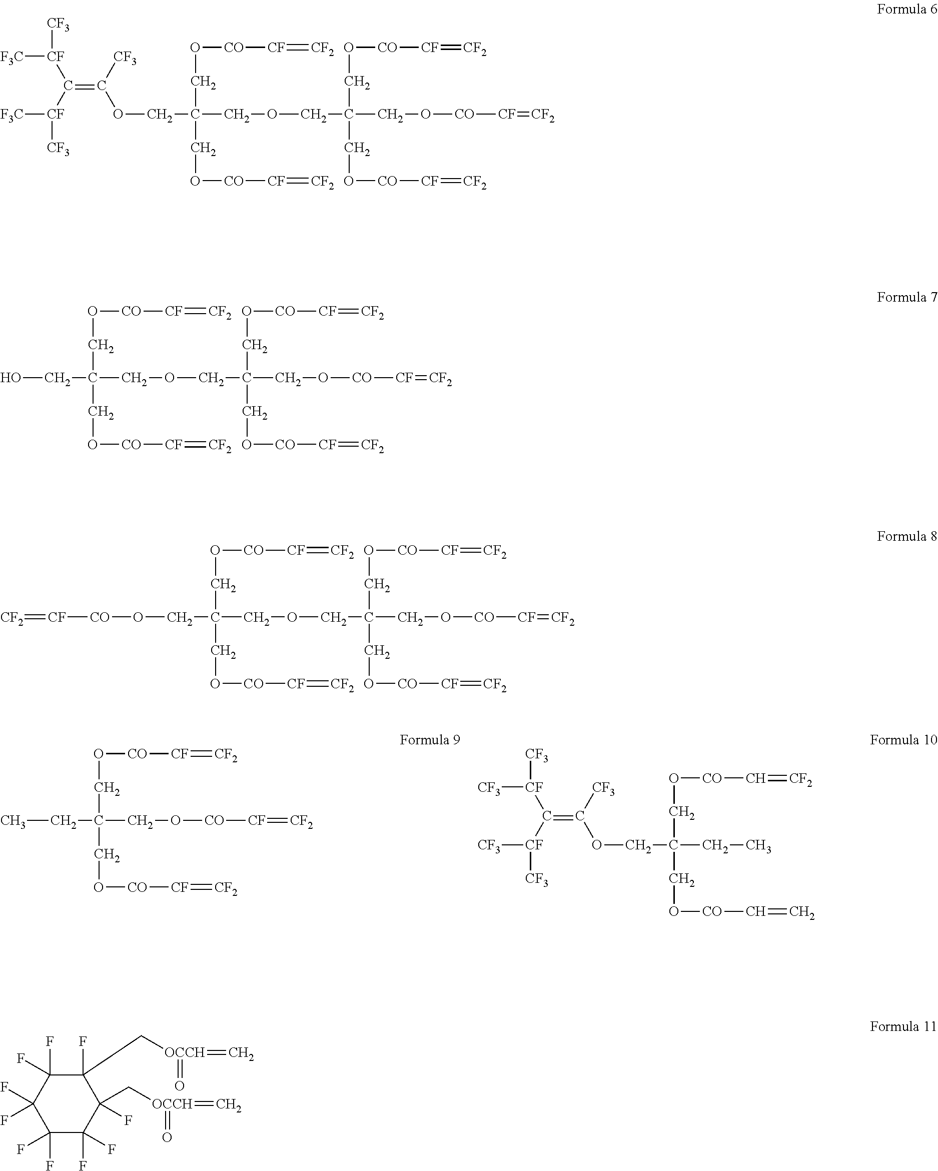 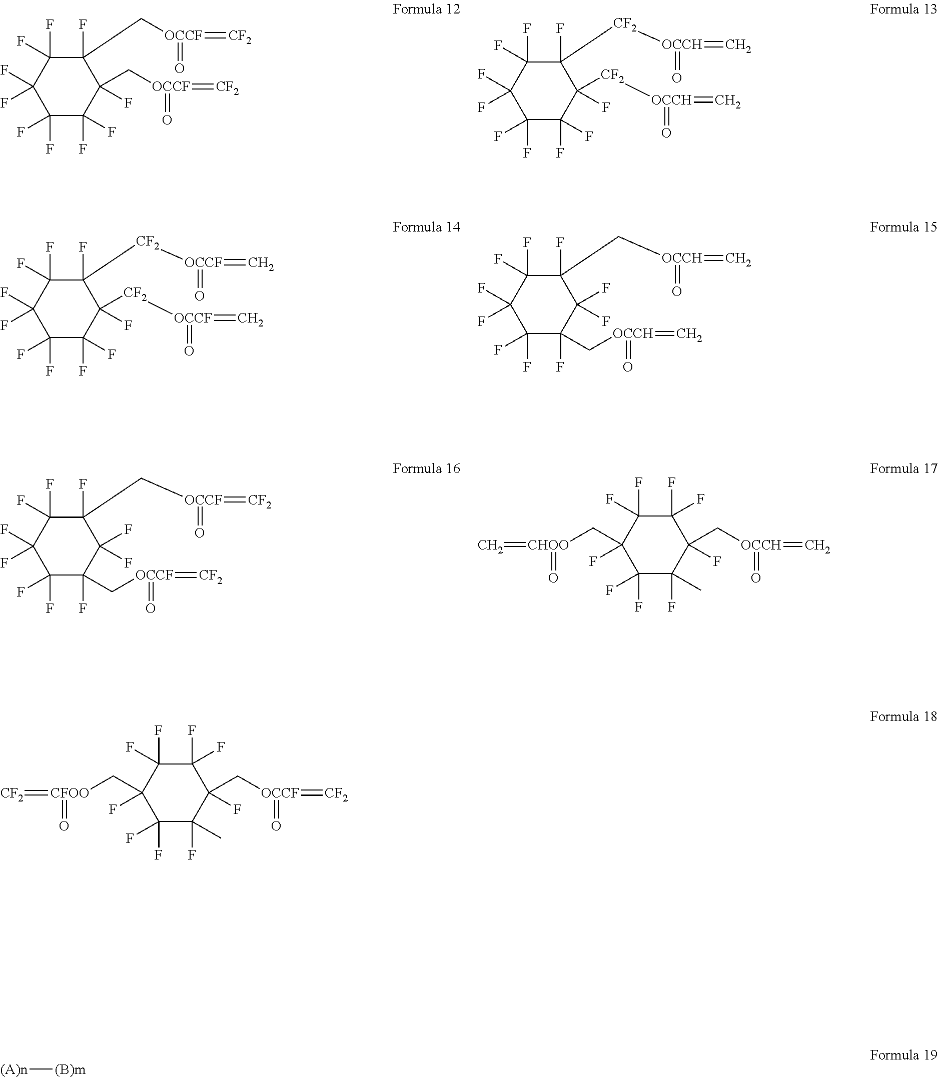
wherein:
A is a fluorine-containing C₁ to C₁₀ alkyl or alkylene group;
B is an acrylate group, methacrylate group, fluorine-substituted acrylate group, or fluorine-substituted methacrylate group;
n is an integer from 1 to 6; and
m is an integer from 1 to 16.

11. The transparent conductor according to claim 7, wherein the fluorine-containing monomer or polymer thereof is present in the second coating layer in an amount of about 2 wt % to about 95 wt %, based on the total weight of the second coating layer.

12. The transparent conductor according to claim 1, wherein the second coating layer is formed from a composition comprising a fluorine-containing monomer or a polymer thereof, a non-fluorine monomer, and an initiator.

13. The transparent conductor according to claim 12, wherein the non-fluorine monomer comprises a monofunctional monomer having a (meth)acrylate group, a polyfunctional monomer having a (meth)acrylate group or a mixture thereof.

14. The transparent conductor according to claim 12, wherein the composition comprises:
about 2 wt % to about 95 wt % of the fluorine-containing monomer or polymer thereof;
about 0.1 wt % to about 95 wt % of the non-fluorine monomer; and
about 0.1 wt % to about 10 wt % of the initiator, based on the total weight of solids in the composition.

15. The transparent conductor according to claim 1, wherein the second coating layer further comprises hollow silica fine particles surface treated with a fluorine-containing resin.

16. The transparent conductor according to claim 1, wherein the first coating layer has a refractive index of about 1.35 to about 1.70 at a wavelength of 380 nm to 780 nm.

17. The transparent conductor according to claim 4, wherein the metal nanowire comprises a silver nanowire.

18. The transparent conductor according to claim 4, wherein the metal nanowire has an aspect ratio of length (L) to diameter (d) of about 10 to about 1,000.

19. The transparent conductor according to claim 1, wherein the base layer comprises a retardation film.

20. The transparent conductor according to claim 1, wherein the base layer comprises polycarbonate, polyester including polyethylene terephthalate, polyethylene naphthalate, polyolefin, cyclic olefin polymers, polysulfone, polyimide, silicone, polystyrene, polyacryl, polyvinyl chloride or a mixture thereof.

21. An apparatus comprising the transparent conductor according to claim 1.
